(19) United States
(12) Patent Application Publication
(10) Pub. No.: US 2024/0291303 A1
(43) Pub. Date: Aug. 29, 2024

(54) LOAD COLLECTIVES FOR ENERGY STORAGE SYSTEMS

(71) Applicant: FLUENCE ENERGY, LLC, Arlington, VA (US)

(72) Inventors: Alejandra Noelia Jolodosky, Washington, DC (US); Colleen Angela Lueken, Arlington, VA (US); Abhishek Ashwani Malik, Pittsburgh, PA (US)

(73) Assignee: FLUENCE ENERGY, LLC, Arlington, VA (US)

(21) Appl. No.: 18/174,122

(22) Filed: Feb. 24, 2023

(51) Int. Cl. H02J 7/00; G06F 1/28; G06Q 50/06

(52) U.S. Cl. CPC H02J 7/0048; G06F 1/28; G06Q 50/06; H02J 7/005

(57) ABSTRACT

Methods, systems, apparatuses, and non-transitory computer-readable media are provided for using load collectives in energy storage systems. In one implementation, the computer-readable media includes instructions to cause a processor to: receive operational data associated with an energy storage unit for a time period; determine one or more cycles of charging and discharging of the energy storage unit during the time period; generate, based on the operational data, a plurality of load collectives; determine one or more operational parameters of the energy storage unit for the time period; provide, to a machine learning model, the one or more operational parameters and one or more load collectives of the plurality of load collectives; generate, based on the machine learning model, a predicted capacity of the energy storage unit at an end of the time period; and configure, based on the predicted capacity, one or more energy storage units.

### TECHNICAL FIELD

The present disclosure generally relates to the field of energy storage. More specifically, the present disclosure relates to energy storage systems using load collectives.

### BACKGROUND

An energy storage system may receive, store, and output energy. The energy storage system, for example, may be connected to an electrical grid, a power station, a building, or any other type of facility, may receive and store energy, and may provide energy at a later time. An operator of an energy storage system may configure how the energy storage system operates, including, for example, configuring the time and rate at which the energy storage system may input or output energy, configuring which unit(s) in the energy storage system may input or output energy, or any other configuring of the energy storage system.

### SUMMARY

As an energy storage is used over time, the capacity of the energy storage may decrease with use. Monitoring the capacity of an energy storage may enable better management of the energy storage. For example, monitoring the capacity of the energy storage may enable augmentation of the capacity when the capacity falls below a threshold. As another example, information on how the capacity of the energy storage changes may help identify any overuse of the energy storage and may help determine how the energy storage may be used in the future (e.g., to reduce overuse). If the capacity of an energy storage is not determined efficiently or accurately, it may result in inefficient management of the energy storage, for example, with respect to determinations that may benefit from considering the capacity of the energy storage.

Disclosed embodiments may relate to systems and methods directed to improving the efficiency and/or accuracy of determining the capacity of an energy storage, for example, by using the operational characteristics of the energy storage to determine the capacity, as described in greater detail herein.

Disclosed embodiments may relate to energy storage systems. Embodiments consistent with the present disclosure provide systems, methods, and apparatuses associated with energy storage.

Disclosed embodiments may include systems, methods, apparatuses, and non-transitory computer-readable media for using load collectives in energy storage systems. For example, disclosed embodiments may include: receiving, by a computing device, operational data associated with an energy storage unit of the one or more energy storage units for a period of time; determining one or more cycles of charging and discharging of the energy storage unit during the period of time; generating, based on the operational data, a plurality of load collectives; determining one or more operational parameters of the energy storage unit for the period of time; providing, to a machine learning model, the one or more operational parameters and one or more load collectives of the plurality of load collectives; generating, based on the machine learning model, a predicted capacity of the energy storage unit at an end of the period of time; and configuring, based on the predicted capacity, the one or more energy storage units. In some embodiments, each load collective of the plurality of load collectives may include: one or more criteria associated with operation of the energy storage unit; and a quantity of cycles, of the one or more cycles, that satisfy the one or more criteria.

Consistent with disclosed embodiments, non-transitory computer-readable media may store instructions that, when executed by at least one processor, may cause the at least one processor to perform any of the processes described herein.

The foregoing general description and the following detailed description are exemplary and explanatory only and are not restrictive of the claims.

### BRIEF DESCRIPTION OF THE DRAWINGS

The accompanying drawings, which are incorporated in and constitute a part of this disclosure, illustrate various disclosed embodiments. In the drawings:

FIG. 1 shows an example system for managing an energy storage system, consistent with some embodiments of the present disclosure.

FIG. 2 shows an example computing device, consistent with some embodiments of the present disclosure.

FIG. 3 shows an example energy storage unit, consistent with some embodiments of the present disclosure.

FIG. 4 shows a flowchart of an example method for using load collectives in energy storage systems, consistent with some embodiments of the present disclosure.

FIG. 5 shows an example of load collectives, consistent with some embodiments of the present disclosure.

FIG. 6 shows an example user interface associated with using load collectives in energy storage systems, consistent with some embodiments of the present disclosure.

FIG. 7 shows an example of a diagram for determining cycles of charging and discharging, consistent with some embodiments of the present disclosure.

### DETAILED DESCRIPTION

The following detailed description refers to the accompanying drawings. Wherever possible, the same reference numbers are used in the drawings and the following description to refer to the same or similar parts. While several illustrative embodiments are described herein, modifications, adaptations, and other implementations are possible. For example, substitutions, additions, or modifications may be made to the components illustrated in the drawings, and the illustrative methods described herein may be modified by substituting, reordering, removing, or adding steps to the disclosed methods. Accordingly, the following detailed description is not limited to the specific embodiments and examples, but is inclusive of general principles described herein and illustrated in the figures in addition to the general principles encompassed by the appended claims.

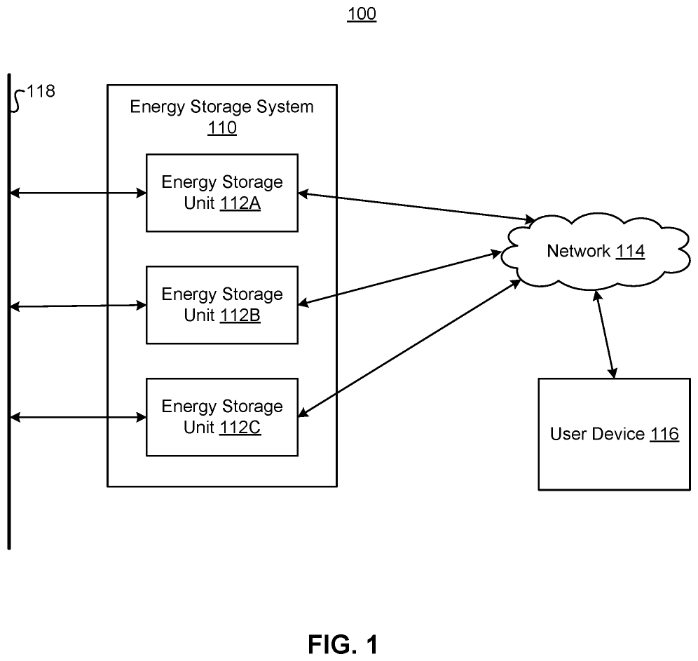

FIG. 1 shows an example system 100 for managing an energy storage system, consistent with some embodiments of the present disclosure. System 100 may include an energy storage system 110, a network 114, a user device 116, and one or more power lines (e.g., a power line 118). Energy storage system 110 may include one or more energy storage units (e.g., 112A, 112B, and 112C).

Network 114 may include one or more of any of various types of networks for communication of information, such as a cellular network (e.g., 2G, 3G, 4G, or 5G), a satellite network, a Wi-Fi network, a WiMAX network, a Bluetooth network, a near-field communication (NFC) network, a low-power wide-area networking (LPWAN) network, a mobile network, a terrestrial microwave network, a wireless ad hoc network, an Ethernet network, a telephone network, a power-line communication (PLC) network, a coaxial cable network, an optical fiber network, and/or the like. Network 114 may include a wired network or a wireless network. Network 114 may include a personal area network, a local area network, a metropolitan area network, a wide area network, a global area network, a space network, or any other type of computer network that may use data connections between network nodes. In some examples, network 114 may include an Internet Protocol (IP) based network. Network 114 may use interconnected communication links to connect energy storage units 112A, 112B, 112C, and/or one or more user devices, such as user device 116.

Energy storage system 110 may refer to any system configured to store energy. Energy storage system 110 may include a centralized system or a distributed system. Energy storage system 110 may include one or more energy storage units (e.g., 112A, 112B, and 112C). In some examples, energy storage units 112A, 112B, 112C may be located in a single physical location, such as a site. In some examples, energy storage units 112A, 112B, 112C may be distributed in multiple physical locations. The energy storage units 112A, 112B, 112C may be interconnected via a network capable of exchanging data and/or energy between the one or more energy storage units 112A, 112B, 112C, and may be configured to function as a system. Although only three energy storage units 112A, 112B, 112C have been described above, it is contemplated that energy storage system 110 may include any number of energy storage units.

Energy storage system 110 may be coupled to one or more power lines (e.g., power line 118). In some examples, power line 118 may be associated with an electrical grid. In some examples, power line 118 may be associated with a power station (e.g., a photovoltaic power station, a solar farm, a wind power station, a wind farm, a hydroelectric power station). In some examples, power line 118 may be associated with any type of facility (e.g., a building, a factory, a hospital, a school, an airport, or any other entity that uses energy). Energy storage system 110 may receive energy via power line 118 and may store the received energy, and/or may output energy via power line 118. For example, energy storage system 110 may include a grid energy storage within an electrical power grid (e.g., an energy storage that may be configured to store electrical energy when electricity is plentiful in an electrical power grid and may be configured to output electrical energy to the electrical power grid when demand for electricity is high). Energy storage system 110 may store electrical energy when demand for electricity is low and may output electrical energy to the grid when demand for electricity is high. As another example, energy storage system 110 may be located next to a solar farm and may be configured to receive electrical energy from the solar farm and store the electrical energy for output at a later time. As another example, energy storage system 110 may be located next to a facility and may be configured to store electrical energy and to provide electrical energy to the facility at an appropriate time.

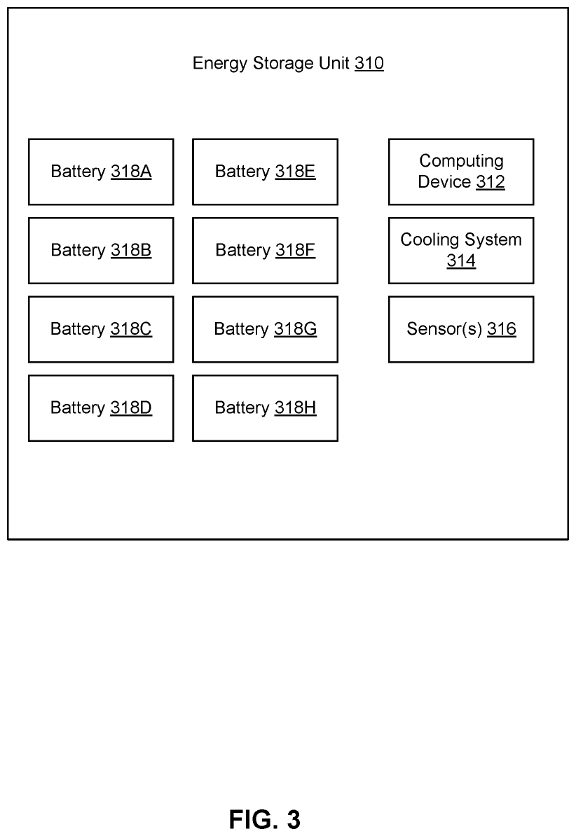

Energy storage system 110 including energy storage unit(s) 112A-112C may store energy in one or more of various forms, such as electrochemical, chemical, mechanical, electrical, electromagnetic, biological, and/or thermal. In some examples, the energy storage system 110 including energy storage unit(s) 112A-112C may store energy using rechargeable batteries. An example of an energy storage unit is described in greater detail in connection with FIG. 3.

User device 116 may include any type of computing device configured to perform one or more of the aspects described herein (e.g., for using load collectives in energy storage systems). For example, user device 116 may include at least one processor and memory storing instructions that, when executed by the at least one processor, cause the at least one processor to perform one or more of the aspects described herein. User device 116 may include, for example, a computer, a laptop computer, a desktop computer, a mainframe computer, a tablet, a smart phone, a mobile phone, a mobile device, a server device, a client device, an automotive electronics device, an extended reality headset, a smart watch, an Internet of things (IoT) device, or any other type of computing device. In some examples, user device 116 may be configured to receive data from various sources (e.g., via network 114), and/or to manage the energy storage system 110. For example, user device 116 may receive operational data of energy storage units 112A, 112B, 112C. Based on received data, user device 116 may manage energy storage system 110. For example, as described in greater detail herein, user device 116 may determine load collectives for the energy storage units 112A, 112B, 112C, may use load collectives for configuring the energy storage units 112A, 112B, 112C, and/or may cause display of user interface(s) that may allow a user (e.g., an administrator or operator for the energy storage system 110) to interact with the energy storage system 110. Although only one user device 116 has been illustrated in FIG. 1 and described above, it is contemplated that system 100 may include any number of user devices.

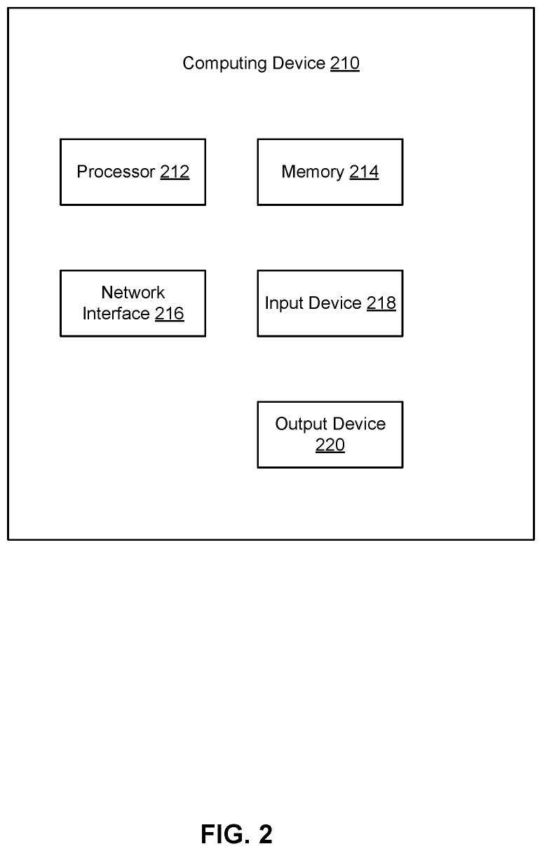

FIG. 2 shows an example computing device 210, consistent with some embodiments of the present disclosure. Computing device 210 may include, for example, at least one processor 212, at least one memory 214, at least one network interface 216, one or more input devices 218, and/or one or more output devices 220. The devices as described herein (e.g., user device 116 shown in FIG. 1, and the computing device 312 shown in FIG. 3) may similarly include these components and/or may be implemented in a similar manner as computing device 210. In some examples, computing device 210 including one or more of the components may be implemented using virtualization technologies and/or cloud computing technologies.

Processor 212 may execute instructions of a computer program to perform any of the functions described herein. Processor 212 may include, for example, integrated circuits, microchips, microcontrollers, microprocessors, central processing units (CPUs), graphics processing units (GPUs), digital signal processors (DSPs), field programmable gate arrays (FPGAs), or other units suitable for executing instructions or performing logic operations. Processor 212 may include a single-core or multiple-core processor (e.g., dual-core, quad-core, or with any desired number of cores). Processor 212 may provide the ability to execute, control, run, or store multiple processes, applications, or programs. In some examples, processor 212 may be configured to provide parallel processing functionalities to allow a device associated with the processor to execute multiple processes simultaneously. In some examples, processor 212 may be configured with virtualization technologies. Other types of processor arrangements may be implemented to provide the capabilities described herein.

Memory 214 may include a non-transitory computer-readable medium that may store instructions that, when executed by at least one processor, cause the at least one processor to perform one or more processes as described herein. A non-transitory computer-readable medium may include any type of physical memory on which information or data readable by at least one processor may be stored. A non-transitory computer-readable medium may include, for example, random access memory (RAM), read-only memory (ROM), compact disc read-only memory (CD-ROM), digital versatile discs (DVDs), programmable read-only memory (PROM), erasable programmable read-only memory (EPROM), non-volatile random-access memory (NVRAM), volatile memory, non-volatile memory, hard drives, flash drives, disks, caches, registers, an optical data storage medium, a physical medium with patterns, or networked versions thereof. A non-transitory computer-readable medium may include multiple structures and may be located at a local location or at a remote location.

Network interface 216 may include, for example, a network card, a modem, and/or the like, and may be configured to provide data communication (e.g., two-way data communication) with a network (e.g., the network 114). Network interface 216 may be a wireless interface, a wired interface, or a combination of the two. The specific design and implementation of network interface 216 may depend on the communication network via which computing device 210 is intended to operate. For example, network interface 216 may include a Wireless Local Area Network (WLAN) card, an Integrated Services Digital Network (ISDN) card, a cellular modem, a satellite modem, a modem configured to provide data communication connections via the Internet, a network card with an Ethernet port, a device with radio frequency receivers and transmitters, a device with optical receivers and transmitters, and/or the like. In some examples, network interface 216 may be designed to operate via network 114. Network interface 216 may be configured to send and receive electrical, electromagnetic, or optical signals that may represent various types of data.

Input device 218 may include, for example, a keyboard, a mouse, a touch pad, a touch screen, one or more buttons, a joystick, a microphone, and/or any other device configured to detect and/or receive input. In some examples, input device 218 may include one or more of various types of sensors, such as an image sensor, a temperature sensor, a humidity sensor, a location sensor, or any other type of sensor. Output device 220 may include, for example, a light indicator, a light source, a display (e.g., a light-emitting diode (LED) display, an organic light-emitting diode (OLED) display, a liquid-crystal display (LCD), or a dot-matrix display), a screen, a touch screen, a speaker, a headphone, a device configured to provide tactile cues, a vibrator, and/or any other device configured to provide output.

Memory 214 may store instructions that, when executed by at least one processor, cause the at least one processor to perform one or more processes as described herein. The instructions may include, for example, software instructions, computer programs, computer code, executable instructions, source code, machine instructions, machine language programs, or any other type of directions for a computing device. The instructions may be based on one or more of various types of desired programming languages, and may include (e.g., embody) various processes for using load collectives in energy storage systems as described herein.

FIG. 3 shows an example energy storage unit 310, consistent with some embodiments of the present disclosure. Energy storage unit 310 may include, for example, a computing device 312, a cooling system 314, one or more sensors 316, and/or one or more batteries (e.g., 318A-318H). Energy storage unit 310 may be an example of one or more of the energy storage units 112A, 112B, 112C. In some examples, energy storage unit 310 may have an enclosure and the components of the energy storage unit 310 may be contained within the enclosure. The enclosure may be in any desired shape, and/or may be constructed using any desired material. For example, the enclosure may have a shape of a rectangular cuboid or a cube.

Computing device 312 may be implemented in a similar manner as the computing device 210. Computing device 312 may be local to energy storage unit 310 (e.g., located within an enclosure of the energy storage unit 310). Computing device 312 may be configured to manage other components of energy storage unit 310. Computing device 312 may, additionally or alternatively, be configured to communicate with another computing device (e.g., user device 116) for managing energy storage unit 310. For example, computing device 312 may transmit operational data of energy storage unit 310 to the other computing device, may receive instructions from the other computing device, and may execute the received instructions.

A battery (e.g., any one of batteries 318A-318H) may refer to an electric battery, and may include a source of electric power including one or more electrochemical cells with external connections. Batteries 318A-318H may be rechargeable, and may be discharged and recharged multiple times. Batteries 318A-318H may include one or more of various types of batteries, such as lithium-ion batteries, lithium iron phosphate batteries, silver-oxide batteries, nickel-zinc batteries, nickel metal hydride batteries, lead-acid batteries, nickel-cadmium batteries, lithium nickel manganese cobalt oxides (NMC) batteries, lithium nickel cobalt aluminium oxides (NCA) batteries, lithium ion manganese oxide (LMO) batteries, lithium cobalt oxide batteries, fuel cells, or other types of batteries. Energy storage unit 310 is illustrated to include batteries 318A-318H, but a larger or smaller number of batteries may be included in energy storage unit 310 as desired.

Batteries 318A-318H may have control components associated therewith. The control components may be, for example, configured to manage the charge and discharge of batteries 318A-318H. The control components may include, for example, battery management systems (BMS). In some examples, each of batteries 318A-318H may have its control component (e.g., a battery management system). The control component for each of batteries 318A-318H may be implemented by a computing device, and/or may communicate with a central management component (e.g., for the energy storage unit 310 and implemented by the computing device 312). Additionally or alternatively, the central management component may manage the charge and discharge of batteries 318A-318H collectively. The charge and discharge of batteries 318A-318H may be controlled using appropriate techniques, such as circuits with switch controls, charge or discharge controllers, charge or discharge regulators, battery regulators, and/or the like, so that batteries 318A-318H may be controlled to be in a state of receiving electricity from a source at a particular rate, in a state of outputting electricity to a load at a particular rate, or in a state of being idle. In some examples, power conversion systems (e.g., for converting alternating current (AC) to direct current (DC), for converting DC to AC, for converting AC to AC, for converting DC to DC, etc.) may be used for coupling batteries 318A-318H to a power line (e.g., the power line 118).

Cooling system 314 may include any type of device configured to remove heat from energy storage unit 310. Cooling system 314 may use air, liquid, solid material, gaseous material, and/or any other type of suitable medium or material to remove heat. In some examples, cooling system 314 may include heat sinks and/or cooling fins. In some examples, cooling system 314 may include fans (e.g., for moving air in air-cooling), pumps (e.g., for moving a liquid in liquid-cooling), compressors (e.g., for vapor-compression refrigeration), or any other type of device for cooling. Cooling system 314 may have any desired configuration (e.g., shape, size, weight, functionality, etc.), and/or may be placed, oriented, or distributed in association with energy storage unit 310 in any desired manner. In some examples, each of batteries 318A-318H may have its individually associated cooling element as part of cooling system 314.

The one or more sensors 316 may include any type of sensor configured to gather information associated with (e.g., measure the operation of) energy storage unit 310. For example, sensor(s) 316 may include temperature sensors, humidity sensors, location sensors, current sensors, voltage sensors, and/or other types of sensors. Sensor(s) 316 may have any desired configuration (e.g., shape, size, weight, functionality, etc.), and/or may be placed, oriented, or distributed in association with energy storage unit 310 in any desired manner. In some examples, each of batteries 318A-318H may have its individually associated sensor(s). For example, each of batteries 318A-318H may have an associated temperature sensor configured to measure a temperature of that battery. In some examples, the energy storage unit 310 may include sensor(s) that may be applicable to batteries 318A-318H collectively. For example, the set of batteries 318A-318H may have an airflow sensor configured to measure a flow rate of air across all the batteries 318A-318H.

Computing device 312 may communicate with and control batteries 318A-318H (e.g., via a control component for each battery), cooling system 314, and sensor(s) 316. In some examples, computing device 312 may control the components based on instructions from another computing device (e.g., user device 116). Additionally or alternatively, data associated with energy storage unit 310 may be gathered, including, for example, data measured by sensor(s) 316, data used by energy storage unit 310 (e.g., parameters for controlling the batteries 318A-318H, or parameters for controlling cooling system 314, such as a fan speed, a pump utilization rate, or a compressor utilization rate), or any other type of data. The gathered data may be processed by computing device 312 and/or another computing device (e.g., user device 116) for one or more aspects described herein.

Disclosed embodiments, including methods, systems, apparatuses, and non-transitory computer-readable media, may relate to using load collectives in energy storage systems. Disclosed embodiments include a system for using load collectives in energy storage systems, the system including: one or more energy storage units and a computing device including at least one processor and at least one memory storing instructions that, when executed by the at least one processor, cause the computing device to perform functions as described herein. An energy storage system may refer to any system configured to store energy. An example of an energy storage system is described in connection with FIG. 1 (e.g., energy storage system 110). An energy storage system may include, for example, one or more energy storage units and/or other suitable components for using, managing, facilitating, or configuring energy storage. An energy storage unit may refer to a physical object for storing energy. An energy storage unit may store energy in one or more of various forms, such as electrochemical, chemical, mechanical, electrical, electromagnetic, biological, and/or thermal. In some examples, an energy storage unit may store energy using rechargeable batteries. An example of an energy storage unit is described in connection with FIG. 3. In some embodiments, the one or more energy storage units include one or more battery units. In some embodiments, each battery unit of the one or more battery units includes an enclosure including a plurality of batteries. The enclosure may be in any desired shape, and/or may be constructed using any desired material. For example, the enclosure may have a shape of a rectangular cuboid or a cube.

A load collective may refer to any information that may characterize, describe, indicate, or be associated with one or more aspects of operation of energy storage (e.g., an energy storage unit) during a time period. A load collective may include, for example, an information item that may characterize one or more aspects of load that an energy storage unit may experience during a time period. In some examples, a load collective may include an item of aggregated information across a time period that may characterize, in a collective manner (e.g., using a counted quantity of occurrences of particular feature(s)), one or more aspects of load that an energy storage unit may experience during the time period. One or more examples of load collectives and one or more examples of using load collectives are described in greater detail below.

Disclosed embodiments include receiving operational data associated with an energy storage unit of the one or more energy storage units for a period of time. For example, a computing device (e.g., user device 116, computing device(s) in energy storage units 112A, 112B, 112C, or any other computing device) may receive operational data associated with an energy storage unit of the one or more energy storage units for a period of time. The operational data associated with the energy storage unit may include any data associated with operation of the energy storage unit. For example, the operational data may include a time series of data points of an aspect (e.g., a temperature, a voltage level, a state of charge, an amount of current, etc.) of the energy storage unit for the period of time. The operational data may be gathered in various ways as desired, and/or may be sent to the computing device. For example, the operational data may be measured by sensor(s) (e.g., sensor(s) 316), which may generate a time series of measured data. In some examples, the operational data may be calculated based on other data (e.g., measured data). In some examples, the operational data may be extracted from a data storage that may store data for operating of the energy storage unit. The period of time may have any desired length (e.g., 1 day, 2 days, 5 days, 10 days, 20 days, 50 days, 100 days, 200 days, 300 days, etc.).

In some embodiments, the operational data includes one or more of: a temperature of the energy storage unit during each of a plurality of intervals of the period of time; a voltage level of the energy storage unit during each of the plurality of intervals of the period of time; a state of charge of the energy storage unit during each of the plurality of intervals of the period of time; or an amount of current of the energy storage unit during each of the plurality of intervals of the period of time. The temperature of the energy storage unit may include, for example, a temperature measured by a sensor (e.g., sensor 316) of the energy storage unit (e.g., 112A-112C, 310), a temperature calculated based on measurements from multiple sensors of the energy storage unit, or any other suitable metric indicating a degree of cold or heat of the energy storage unit. In some examples, the energy storage unit may be configured with multiple temperature sensors. For example, each of the multiple temperature sensors may be associated with a battery of a plurality of batteries (e.g., 318A-318H) of the energy storage unit. The temperature of the energy storage unit may be represented as an aggregation of temperature measurements from the multiple temperature sensors (e.g., an average of the temperature measurements, a maximum of the temperature measurements, a minimum of the temperature measurements, or any other statistic or metric). The temperature of the energy storage unit may be determined for each of a plurality of intervals of the period of time. In some examples, the operational data may include a time series of data points indicating the temperature of the energy storage unit for each of a plurality of intervals of the period of time.

The voltage level of the energy storage unit may include, for example, a voltage level between points (e.g., the external connections, the terminals, etc.) of the energy storage unit that may be measured by a sensor, or any other suitable metric indicating a voltage associated with the energy storage unit (e.g., 112A-112C, 310). In some examples, the voltage level of the energy storage unit may be a metric determined based on voltage measurements from multiple sensors (e.g., sensors 316) of the energy storage unit. For example, the energy storage unit may be configured with multiple voltage sensors. Each of the multiple voltage sensors may be configured to measure a voltage level of a battery of a plurality of batteries of the energy storage unit (e.g., a voltage level between the terminals of the battery). The voltage level of the energy storage unit may be represented as an aggregation of voltage measurements from the multiple voltage sensors (e.g., an average of the voltage measurements, a maximum of the voltage measurements, a minimum of the voltage measurements, a sum of the voltage measurements, or any other statistic or metric). The voltage level of the energy storage unit may be determined for each of a plurality of intervals of the period of time. In some examples, the operational data may include a time series of data points indicating the voltage level of the energy storage unit for each of a plurality of intervals of the period of time.

The state of charge of the energy storage unit (e.g., 112A-112C, 310) may refer to a level of charge of the energy storage unit relative to its capacity. The state of charge of the energy storage unit may be measured in various ways as desired. For example, the state of charge of the energy storage unit may be calculated based on voltage level(s) associated with the energy storage unit (e.g., the voltage level of the energy storage unit, voltage levels of batteries of the energy storage unit, etc.). A mapping between the voltage level(s) associated with the energy storage unit and the state of charge of the energy storage unit may be used to determine the state of charge of the energy storage unit. As another example, the state of charge of the energy storage unit may be calculated based on measurements of electric current flowing into or out of the energy storage unit (e.g., input current or output current). The state of charge of the energy storage unit may be calculated based on measuring and integrating the current over time (e.g., using a coulomb counting method). In some examples, the state of charge of the energy storage unit may be determined based on data used to control the energy storage unit to charge or discharge. For example, data associated with an energy dispatch pattern may indicate that the energy storage unit may be configured to charge or discharge at a particular rate (e.g., Volts per hour, Volts per second, Amperes per hour, Amperes per second, Watts per hour, Watts per second, etc.) during a time segment. The data may be used to calculate or track the state of charge of the energy storage unit. The state of charge of the energy storage unit may be determined using any other suitable method, or using a combination of two or more of the above described methods. The state of charge of the energy storage unit may be determined for each of a plurality of intervals of the period of time. In some examples, the operational data may include a time series of data points indicating the state of charge of the energy storage unit for each of a plurality of intervals of the period of time.

The amount of current of the energy storage unit may include, for example, an amount of electric current that may flow out of the energy storage unit, an amount of current that may flow into the energy storage unit, or any other suitable metric indicating an amount of current associated with the energy storage unit. The amount of current of the energy storage unit may be, for example, measured by one or more sensors (e.g., current sensors). The sensor(s) (e.g., sensor(s) 316) may measure current that may flow out of or into the energy storage unit at suitable point(s) (e.g., external connection(s), terminal(s), etc.) of the energy storage unit. In some examples, current sensor(s) may measure the current that may flow out of or into each of a plurality of batteries of the energy storage unit. The amount of current of the energy storage unit may be determined based on measurements from current sensors for the plurality of batteries (e.g., an aggregation of the measurements, an average of the measurements, a maximum of the measurements, a minimum of the measurements, a sum of the measurements, or any other statistic or metric). The amount of current of the energy storage unit may be determined for each of a plurality of intervals of the period of time. In some examples, the operational data may include a time series of data points indicating the amount of current of the energy storage unit for each of a plurality of intervals of the period of time.

The time intervals for the measurements, determinations, or time series of data points, for the various aspects of the energy storage unit (e.g., a temperature, a voltage level, a state of charge, or an amount of current, etc.) may have any desired configuration. For example, the time intervals for different aspects of the energy storage unit may be the same or have the same configuration (e.g., length). As another example, the time intervals for different aspects of the energy storage unit may be different or have different configurations. In some examples, the time intervals for a particular aspect of the energy storage unit may have the same length or may have different lengths. Additionally or alternatively, a time interval within the period of time may have any desired length (e.g., 0.1 seconds, 0.5 seconds, 1 second, 2 seconds, 5 seconds, 10 seconds, 30 seconds, 1 minute, 2 minutes, 5 minutes, etc.). In some examples, the time intervals may be determined by dividing the period of time into a number of consecutive segments of time. In some examples, the operational data may include any other type of suitable data associated with the energy storage unit (e.g., a degree of humidity in an area in which the energy storage unit is located, an energy dispatch pattern for the energy storage unit indicating a rate at which the energy storage unit may be configured to charge or discharge during each of multiple time segments, etc.). In some examples, operational data may be gathered for any other type of device, component, or element for energy storage (e.g., on a larger or smaller scale than the energy storage unit, such as gathering operational data for multiple energy storage units collectively or gathering operational data for a battery individually within an energy storage unit), and the processes described herein (e.g., the processes associated with the energy storage unit) may be similarly applicable to any other type of device, component, or element for energy storage.

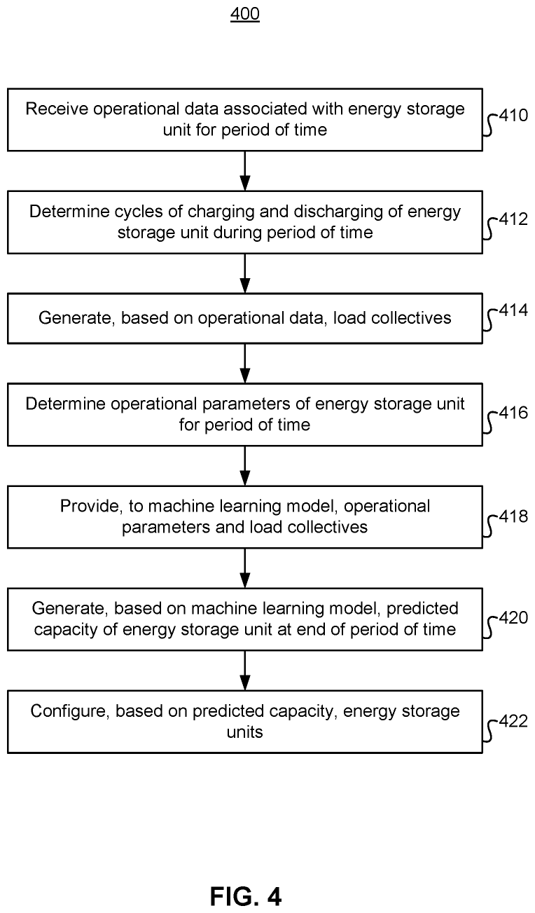

FIG. 4 shows a flowchart of an example method 400 for using load collectives in energy storage systems, consistent with some embodiments of the present disclosure. With reference to FIG. 4, in step 410, a computing device may receive operational data associated with an energy storage unit of the one or more energy storage units for a period of time. Method 400 may be performed by any computing device (e.g., user device 116, computing device(s) in energy storage units 112A, 112B, 112C, computing device 210, computing device 312, a computing device associated with energy storage system 110, and/or any other computing device).

Disclosed embodiments include determining one or more cycles of charging and discharging of the energy storage unit during the period of time. For example, the computing device may identify cycles of charging and discharging of the energy storage unit during a particular period of time. A cycle of charging and discharging may refer to a series of events including charging of an energy storage, discharging of an energy storage, and/or an energy storage being idle (e.g., neither charging nor discharging). Charging of an energy storage may include, for example, the energy storage receiving energy. Discharging of an energy storage may include, for example, the energy storage outputting energy. The cycle including a series of events of charging, discharging, and/or being idle may have any desired number of events and/or may have the events in any desired order. For example, a cycle may include a time segment of charging, followed by a time segment of discharging. As another example, a cycle may include a time segment of discharging, followed by a time segment of charging. In some examples, a cycle may include time segments of charging and discharging separated by a time segment of being idle. In some examples, a cycle may include multiple time segments of charging, multiple time segments of discharging, and/or multiple time segments of being idle.

The computing device may identify one or more cycles of charging and discharging of the energy storage unit during a given period of time using one or more methods. The one or more cycles of charging and discharging may be determined based on operational data associated with the energy storage unit. For example, a time series of data points indicating the state of charge of the energy storage unit may be used to determine the one or more cycles of charging and discharging. Increasing of the state of charge of the energy storage unit may indicate charging of the energy storage unit, and decreasing of the state of charge of the energy storage unit may indicate discharging of the energy storage unit. As one example, the computing device may use the data of the state of charge to identify cycles, and each of the cycles may include a time segment of charging and a time segment of discharging. The occurrence of one or more cycles of charging and discharging may be identified by processing the time series of the state of charge data. In some examples, other types of suitable data associated with the energy storage unit (e.g., data indicating when the energy storage unit may be charging or discharging) may be used to identify one or more cycles of charging and discharging.

Disclosed embodiments include determining the one or more cycles of charging and discharging of the energy storage unit during the period of time using a rain-flow counting algorithm. For example, the computing device may determine the one or more cycles of charging and discharging of the energy storage unit during the period of time using a rain-flow counting algorithm. A rain-flow counting algorithm may use data indicating the state of charge of the energy storage unit during the period of time (e.g., a time series of data points indicating the state of charge for the period of time). The rain-flow algorithm may use a pagoda roof method, a four point method, or any other desired method.

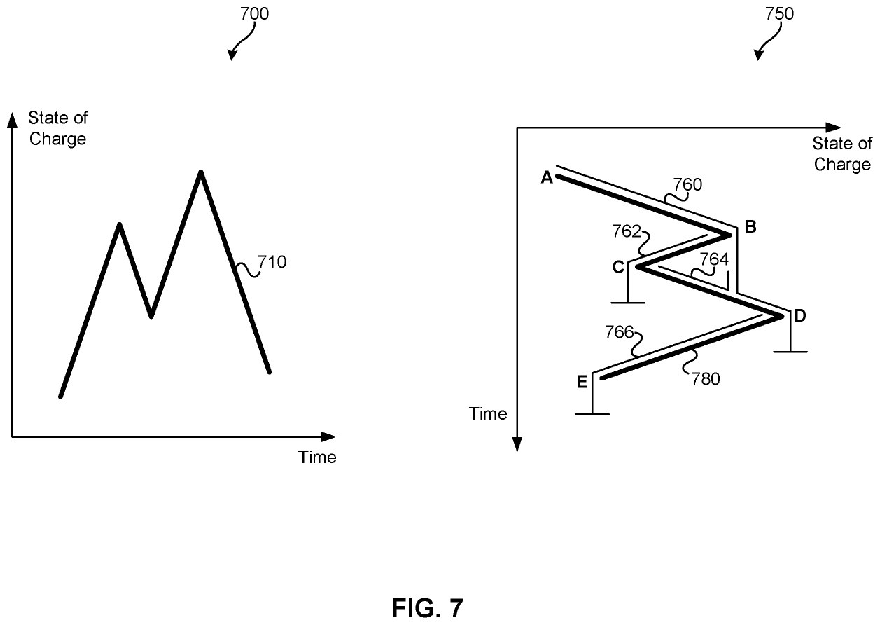

FIG. 7 shows an example of a diagram for determining cycles of charging and discharging, consistent with some embodiments of the present disclosure. With reference to FIG. 7, as one example, using the pagoda roof method, a time series of data points indicating the state of charge of the energy storage unit for the period of time may be represented using a two-dimensional coordinate system 700. The x-axis of the coordinate system 700 may represent time, and the y-axis of the coordinate system 700 may represent the state of charge of the energy storage unit (e.g., 0% to 100%). Data of the state of charge of the energy storage unit over the period of time may be represented as, or may be processed to be represented as, a number of line segments 710 in the coordinate system 700 (e.g., resembling a continuous piecewise linear function). The line segments 710 may indicate, for example, increase, decrease, or being unchanged of the state of charge of the energy storage unit in time, and/or may indicate, for example, charging, discharging, or being idle of the energy storage unit in time. Using the pagoda roof method, the coordinate system 700 and the line segments 710 therein (e.g., together as an image) may be turned clockwise 90 degrees of arc, to result in a diagram 750. The line segments 780 in the diagram 750 (corresponding to the line segments 710) may be treated as a series of pagoda roofs. The pagoda roof method may consider the flow of water down the series of pagoda roofs. Regions where the water may not flow may identify a cycle which may be seen as an interruption to another cycle. The pagoda roof method may include considering a flow of water or rain starting at each successive extremum point (e.g., maximum point or minimum point, such as point A or point D in the diagram 750). The pagoda roof method may include identifying a loading reversal (e.g., a half cycle) by allowing each rain-flow to continue to drip down the roofs until: it falls opposite a larger maximum (or smaller minimum) point; it meets a previous flow falling from above; or it falls below the roof. The pagoda roof method may include identifying each hysteresis loop (e.g., a full cycle) by pairing up the same counted reversals (e.g., reversals having the same magnitude and opposite directions). For example, a flow of water 760 may start at point A in the diagram 750, and may drip down the roofs via point B and point D, and the reversal from point A to point D may be identified as a half cycle. A flow of water 766 may start at point D in the diagram 750, and may drip down the roofs via point E, and the reversal from point D to point E may be identified as a half cycle. A flow of water 762 may start at point B in the diagram 750, and may drip down the roofs via point C, and the reversal from point B to point C (reversal B-C) may be identified as a half cycle. A flow of water 764 may start at point C in the diagram 750, and may drip down the roofs until a particular point in the diagram 750 having the same magnitude of the state of charge as point B, and the reversal from point C to the particular point corresponding to point B (reversal C-B) may be identified as a half cycle. A full cycle between a state of charge (e.g., point B) and another state of charge (e.g., point C) may be identified by paring the reversal B-C and the reversal C-B.

Using the rain-flow counting algorithm (e.g., the pagoda roof method), the one or more cycles of charging and discharging of the energy storage unit during the period of time may be identified. The identified one or more cycles of charging and discharging may include one or more of various types of cycles as determined using the rain-flow counting algorithm (e.g., full cycles as determined using the rain-flow counting algorithm, half cycles as determined using the rain-flow counting algorithm, etc.). For example, the identified one or more cycles of charging and discharging may include full cycles as determined using the rain-flow counting algorithm and half cycles as determined using the rain-flow counting algorithm (e.g., those half cycles each of which is not able to be paired up with another half cycle to form a full cycle and/or is not included in any full cycle after all of the full cycles are determined). As another example, the identified one or more cycles of charging and discharging may include full cycles as determined using the rain-flow counting algorithm. As another example, the identified one or more cycles of charging and discharging may include half cycles as determined using the rain-flow counting algorithm. With reference to FIG. 4, in step 412, the computing device may determine one or more cycles of charging and discharging of the energy storage unit that may occur during the period of time.

Disclosed embodiments include generating, based on the operational data, a plurality of load collectives. For example, the computing device may generate, based on the operational data associated with the energy storage unit, a plurality of load collectives. A load collective may refer to any information that may characterize, describe, indicate, or be associated with one or more aspects of operation of energy storage (e.g., an energy storage unit) during a time period. A load collective may include, for example, an information item that may characterize one or more aspects of load (e.g., an amount of energy or power inputted or outputted) that an energy storage unit may experience during a time period. In some examples, a load collective may include an item of aggregated information across a time period that may characterize, in a collective manner (e.g., using a counted quantity of occurrences of particular feature(s)), one or more aspects of load that an energy storage unit may experience during the time period.

In some embodiments, each load collective of the plurality of load collectives includes: one or more criteria associated with operation of the energy storage unit; and a quantity of cycles, of the determined one or more cycles of charging and discharging of the energy storage unit during the period of time, that satisfy the one or more criteria. A criterion associated with operation of the energy storage unit may refer to any type of rule, standard, pattern, or principle associated with operation of the energy storage unit. A feature, characteristic, or property of a cycle of the one or more cycles (e.g., calculated based on operational data associated with the energy storage unit during the time range of the cycle, etc.) may be compared with respect to the criterion to determine whether the cycle satisfies the criterion.

In some embodiments, the one or more criteria associated with operation of the energy storage unit include one or more of: a range of a temperature of the energy storage unit; a range of a voltage level of the energy storage unit; a range of a minimum state of charge of the energy storage unit; a range of a maximum state of charge of the energy storage unit; a range of a sum of amounts of current of the energy storage unit; a range of a sum of current squared of the energy storage unit during a time segment; a range of an amount of current of the energy storage unit; or a range of a depth of charge of the energy storage unit. With regard to the range of the temperature of the energy storage unit, the temperature may refer to any type of indication of cold or heat of the energy storage unit, such as an average temperature of the energy storage unit during the time range of a cycle, a portion or entirety of temperature data points (e.g., of a time series) of the energy storage unit during the time range of a cycle, or any other statistic or metric. Determining whether a cycle of charging and discharging satisfies a criterion based on a range of the temperature of the energy storage unit may include determining whether the temperature of the energy storage unit during the cycle (e.g., as determined based on operational data for a time range of the cycle) falls within the range of the temperature defined by the criterion.

With regard to the range of the voltage level of the energy storage unit, the voltage level may refer to any type of voltage indication of the energy storage unit, such as an average voltage level of the energy storage unit during the time range of a cycle, a portion or entirety of voltage level data points (e.g., of a time series) of the energy storage unit during the time range of a cycle, or any other statistic or metric. Determining whether a cycle of charging and discharging satisfies a criterion based on a range of the voltage level of the energy storage unit may include determining whether the voltage level of the energy storage unit during the cycle (e.g., as determined based on operational data for a time range of the cycle) falls within the range of the voltage level defined by the criterion.

With regard to the range of the minimum state of charge of the energy storage unit, the minimum state of charge may refer to, for example, a minimum of the state of charge of the energy storage unit during the time range of a cycle. Determining whether a cycle of charging and discharging satisfies a criterion based on a range of the minimum state of charge of the energy storage unit may include determining whether the minimum state of charge of the energy storage unit during the cycle (e.g., as determined based on operational data for a time range of the cycle) falls within the range of the minimum state of charge defined by the criterion.

With regard to the range of the maximum state of charge of the energy storage unit, the maximum state of charge may refer to, for example, a maximum of the state of charge of the energy storage unit during the time range of a cycle. Determining whether a cycle of charging and discharging satisfies a criterion based on a range of the maximum state of charge of the energy storage unit may include determining whether the maximum state of charge of the energy storage unit during the cycle (e.g., as determined based on operational data for a time range of the cycle) falls within the range of the maximum state of charge defined by the criterion.

With regard to the range of the sum of amounts of current of the energy storage unit, the sum of amounts of current may refer to, for example, a sum of data points (e.g., of a time series) of the amount of current of the energy storage unit during the time range of a cycle, or a sum of the absolute value of each data point (e.g., of a time series) of the amount of current of the energy storage unit during the time range of a cycle. Determining whether a cycle of charging and discharging satisfies a criterion based on a range of the sum of amounts of current of the energy storage unit may include determining whether the sum of amounts of current of the energy storage unit during the cycle (e.g., as determined based on operational data for a time range of the cycle) falls within the range of the sum of amounts of current defined by the criterion.

With regard to the range of the sum of current squared of the energy storage unit during a time segment, the sum of current squared may refer to, for example, a sum of the square of each data point (e.g., of a time series) of the amount of current of the energy storage unit during the time range of a cycle, and the sum of current squared during a time segment may refer to, for example, the sum (of current squared) divided by the length of the time range of the cycle. Determining whether a cycle of charging and discharging satisfies a criterion based on a range of the sum of current squared of the energy storage unit during a time segment may include determining whether the sum of current squared of the energy storage unit during a time segment for the cycle (e.g., as determined based on operational data for a time range of the cycle) falls within the range of the sum of current squared defined by the criterion.

With regard to the range of the amount of current of the energy storage unit, the amount of current may refer to any type of indication of current associated with the energy storage unit, such as an average of data points (e.g., of a time series) of the amount of current of the energy storage unit during the time range of a cycle, an average of the absolute value of each data point (e.g., of a time series) of the amount of current of the energy storage unit during the time range of a cycle, a portion or entirety of data points (e.g., of a time series) of the amount of current of the energy storage unit during the time range of a cycle, a portion or entirety of the absolute values of data points (e.g., of a time series) of the amount of current of the energy storage unit during the time range of a cycle, or any other statistic or metric. In some examples, two or more criteria related to the amount of current may be used separately for charging or discharging of the energy storage unit. Determining whether a cycle of charging and discharging satisfies a criterion based on a range of the amount of current of the energy storage unit may include determining whether the amount of current of the energy storage unit during the cycle (e.g., as determined based on operational data for a time range of the cycle) falls within the range of the amount of current defined by the criterion.

With regard to the range of the depth of charge of the energy storage unit, the depth of charge may refer to, for example, a difference between a maximum of the state of charge of the energy storage unit during the time range of a cycle and a minimum of the state of charge of the energy storage unit during the time range of the cycle. Determining whether a cycle of charging and discharging satisfies a criterion based on a range of the depth of charge of the energy storage unit may include determining whether the depth of charge of the energy storage unit during the cycle (e.g., as determined based on operational data for a time range of the cycle) falls within the range of the depth of charge defined by the criterion.

A set of one or more criteria for each load collective of the plurality of load collectives may be different from the set of one or more criteria for another load collective of the plurality of load collectives. In some embodiments, one or more criteria associated with operation of the energy storage unit for a first load collective of the plurality of load collectives are different from one or more criteria associated with operation of the energy storage unit for a second load collective of the plurality of load collectives. For example, a set of one or more criteria for a first load collective may include one or more of a temperature range of 20-22 degrees Celsius, a voltage level range of 720-740 volts, a range of a maximum state of charge of 80%-90%, a range of a minimum state of charge of 0%-10%, and/or a range of a sum of amounts of current of 1-1200 amperes. In contrast, a set of one or more criteria for a second load collective may include one or more of a temperature range of 24-26 degrees Celsius, a voltage level range of 760-780 volts, a range of a maximum state of charge of 80%-90%, a range of a minimum state of charge of 0%-10%, and/or a range of a sum of amounts of current of 1200-2400 amperes. The computing device may determine various sets of one or more criteria for the plurality of load collectives (e.g., based on input from an operator of the energy storage unit).

In some examples, outer bounds of each type of the one or more criteria may be specified (e.g., a criterion associated with temperature may have a lower bound of 20 degrees Celsius and an upper bound of 30 degrees Celsius; a criterion associated with voltage level may have a lower bound of 700 volts and an upper bound of 800 volts; etc.), and the span between the outer bounds may be divided into a number of ranges (e.g., the span of 20-30 degrees Celsius for the temperature criterion may be divided into the ranges of 20-22 degrees Celsius, 22-24 degrees Celsius, 24-26 degrees Celsius, 26-28 degrees Celsius, and 28-30 degrees Celsius; the span of 700-800 volts for the voltage level criterion may be divided into the ranges of 700-720 volts, 720-740 volts, 740-760 volts, 760-780 volts, and 780-800 volts; etc.). The various sets of one or more criteria may be generated based on, for each set of the various sets, selecting a range option for each type of the one or more criteria of the set, where each criterion type may have a number of range options (e.g., the temperature criterion may have the range options of 20-22 degrees Celsius, 22-24 degrees Celsius, 24-26 degrees Celsius, 26-28 degrees Celsius, and 28-30 degrees Celsius; the voltage level criterion may have the range options of 700-720 volts, 720-740 volts, 740-760 volts, 760-780 volts, and 780-800 volts; etc.). In some examples, as multiple types of criteria may be included in a set, the total number of the generated sets may be calculated according to the rule of product. In some examples, a portion or entirety of the generated sets may be used for load collectives.

To generate a particular load collective, the computing device may, for example, determine the time range of each cycle (e.g., of the determined one or more cycles) of charging and discharging of the energy storage unit during the period of time, and determine operational data (e.g., temperature, voltage level, state of charge, amount of current) associated with the energy storage unit for the time range (e.g., a span between a first time instance and a second time instance) of each cycle. For each cycle, the computing device may determine, based on the operational data for the cycle, metrics that may be compared with respect to the one or more criteria associated with the particular load collective. For example, based on the operational data for the cycle, the computing device may determine metrics for the cycle (e.g., a temperature of the energy storage unit for the cycle, a voltage level of the energy storage unit for the cycle, etc.). The computing device may compare the determined metrics for the cycle with respect to the corresponding one or more criteria of the particular load collective, to determine whether each of the determined metrics satisfies the corresponding criterion for the particular load collective (e.g., by determining whether the value of the metric falls within the range of the corresponding criterion). When each of the determined metrics for the cycle satisfies the corresponding criterion of the one or more criteria of the particular load collective, the computing device may determine that the cycle satisfies the one or more criteria of the particular load collective, and may increase, by one (1), a counted quantity of cycles, of the particular load collective, that satisfy the one or more criteria of the particular load collective. If it is not the case that each of the determined metrics for the cycle satisfies the corresponding criterion of the one or more criteria of the particular load collective, the computing device may determine that the cycle does not satisfy the one or more criteria of the particular load collective, and may not increment the counted quantity of cycles for the particular load collective. The computing device may perform the above processes for each cycle of the determined one or more cycles of charging and discharging of the energy storage unit during the period of time, to determine the quantity (or number) of cycles that satisfy the one or more criteria for the particular load collective. The computing device may similarly determine other load collectives of the plurality of load collectives (e.g., including determining, for each of the other load collectives, the quantity (or number) of cycles that satisfy the one or more criteria for that load collective).

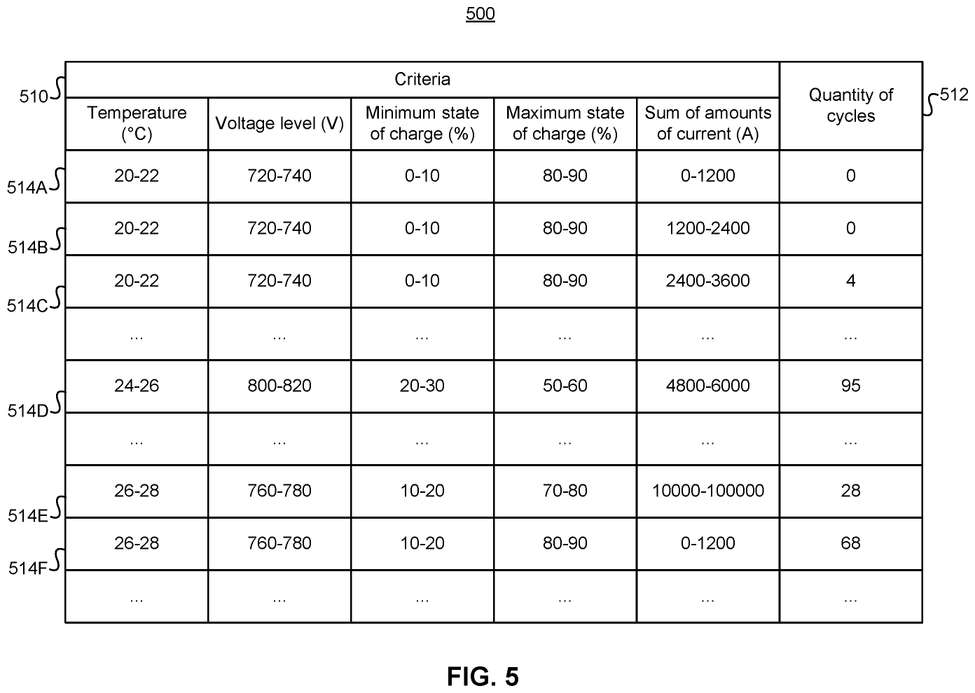

FIG. 5 shows an example of load collectives 500, consistent with some embodiments of the present disclosure. Criteria 510 for the load collectives 500 (e.g., for an energy storage unit for a period of time) may include, for example, a range of a temperature of the energy storage unit (represented using degrees Celsius), a range of a voltage level of the energy storage unit (represented using volts), a range of a minimum state of charge of the energy storage unit (represented using a percentage), a range of a maximum state of charge of the energy storage unit (represented using a percentage), and a range of a sum of amounts of current of the energy storage unit (represented using amperes). An indication 512 shows a quantity (e.g., a number or count) of cycles that may satisfy the corresponding criteria. Load collectives 500 may include a number of load collectives (e.g., based on different combinations of each criterion having various options of a range or value). Examples of load collectives may include load collectives 514A, 514B, 514C, 514D, 514E, 514F (e.g., shown as various rows in the table of FIG. 5). For example, the criteria for load collective 514D may include a range of a temperature of the energy storage unit of 24-26 degrees Celsius, a range of a voltage level of the energy storage unit of 800-820 volts, a range of a minimum state of charge of the energy storage unit of 20%-30%, a range of a maximum state of charge of the energy storage unit of 50%-60%, and a range of a sum of amounts of current of the energy storage unit of 4800-6000 amperes. The load collective 514D may include a quantity (e.g., a number or count) of cycles (e.g., 95 cycles) that may satisfy the criteria for the load collective 514D (e.g., each of the 95 cycles may have metrics that may be determined based on operational data of the energy storage unit for the cycle, and each of the metrics may fall within the range of the corresponding criterion of the criteria of the load collective 514D).

In some examples, the one or more criteria of a load collective may include a range of a temperature of the energy storage unit, a range of a voltage level of the energy storage unit, a range of a minimum state of charge of the energy storage unit, a range of a maximum state of charge of the energy storage unit, and a range of a sum of amounts of current (e.g., the absolute values of the current) of the energy storage unit. In some examples, the one or more criteria of a load collective may consist of a range of a temperature of the energy storage unit, a range of a voltage level of the energy storage unit, a range of a minimum state of charge of the energy storage unit, a range of a maximum state of charge of the energy storage unit, and a range of a sum of amounts of current (e.g., the absolute values of the current) of the energy storage unit. The one or more criteria of the load collective may capture information regarding a throughput of the energy storage unit.

In some examples, the one or more criteria associated with a load collective may include a range of a temperature of the energy storage unit, a range of a voltage level of the energy storage unit, a range of a depth of charge of the energy storage unit, and a range of a sum of current squared of the energy storage unit during a time segment (e.g., the sum (of current squared) divided by the length of the time range of a cycle). In some examples, the one or more criteria associated with a load collective may consist of a range of a temperature of the energy storage unit, a range of a voltage level of the energy storage unit, a range of a depth of charge of the energy storage unit, and a range of a sum of current squared of the energy storage unit during a time segment (e.g., the sum (of current squared) divided by the length of the time range of a cycle).

Additionally or alternatively, a load collective may be in any other desired form. For example, the criteria associated with a load collective may include or consist of ranges of a temperature, a voltage level, a depth of charge, an amount of current for charging, and an amount of current for discharging, of the energy storage unit. In some examples, a load collective may indicate a quantity of cycles having a particular maximum state of charge and having a particular minimum state of charge (or having a maximum state of charge falling within a particular range and having a minimum state of charge falling within a particular range). In some examples, a load collective may include one or more criteria and a counted quantity of time intervals or time instances, where the data points associated with the energy storage unit for each time interval of the time intervals or for each time instance of the time instances may satisfy the one or more criteria (e.g., the data points may include a temperature data point in a time series and a voltage level data point in a time series, and the one or more criteria may include a temperature range and a voltage level range). In some examples, a load collective may indicate a quantity of data points, for one or more aspects associated with the energy storage unit, that may satisfy one or more criteria (e.g., a quantity of temperature data points that may fall within a temperature range).

With reference to FIG. 4, in step 414, the computing device may generate, based on the operational data, a plurality of load collectives. Each load collective of the plurality of load collectives may include: one or more criteria associated with operation of the energy storage unit; and a quantity of cycles, of the one or more cycles, that satisfy the one or more criteria (e.g., a quantity of cycles that satisfy the one or more criteria out of the total number of cycles identified in, for example, step 412).

Disclosed embodiments include determining one or more operational parameters of the energy storage unit for the period of time. For example, the computing device may determine one or more operational parameters of the energy storage unit for the period of time. The one or more operational parameters may be determined, for example, based on the operational data associated with the energy storage unit for the period of time and/or other suitable data. An operational parameter may include any type of information associated with operation of energy storage (e.g., the energy storage unit). In some embodiments, the one or more operational parameters of the energy storage unit include one or more of: a quantity of cycles, of charging and discharging of the energy storage unit during the period of time, determined using a rain-flow counting algorithm; a quantity of equivalent full cycles of charging and discharging of the energy storage unit during the period of time; a sum of amounts of current of the energy storage unit during the period of time; an average state of charge of the energy storage unit during the period of time; a length of the period of time; or a capacity of the energy storage unit at a beginning of the period of time. For example, the computing device may determine, based on the operational data associated with the energy storage unit for the period of time (e.g., the data indicating the state of charge of the energy storage unit during the period of time), and using a rain-flow counting algorithm, cycles of charging and discharging of the energy storage unit. The computing device may count the quantity of the determined cycles (e.g., may determine a total number or count of the determined cycles) as an operational parameter.

As another example, the computing device may determine an operational parameter for an energy storage unit as a quantity of equivalent full cycles of charging and discharging of the energy storage unit during the period of time. A quantity of equivalent full cycles may refer to, for example, a measurement of throughput of the energy storage unit. A quantity of equivalent full cycles may include a quantity of cycles of charging fully to the capacity of the energy storage unit (e.g., charging to approximately 100% of the capacity) and discharging fully of the energy storage unit (e.g., discharging to approximately 0% of the capacity). Based on the operational data associated with the energy storage unit for the period of time (e.g., the data indicating the state of charge of the energy storage unit during the period of time), the computing device may determine the quantity (e.g., a number) of equivalent full cycles to which the charging and discharging of the energy storage unit during the period of time may be equivalent. For example, the computing device may determine a first sum of the percentage changes of the state of charge of the energy storage unit for charging and determine a second sum of the percentage changes of the state of charge of the energy storage unit for discharging. The computing device may determine the number of equivalent full cycles that may correspond to the first sum and the second sum.

In some embodiments, the computing device may determine an operational parameter for an energy storage unit as a sum of amounts of current of the energy storage unit during the period of time (e.g., a sum of the absolute values of the data points (e.g., in a time series) of the amount of current of the energy storage unit for the period of time). In some embodiments, the computing device may determine an operational parameter for an energy storage unit as an average state of charge of the energy storage unit during the period of time (e.g., an average of the data points (e.g., in a time series) of the state of charge of the energy storage unit for the period of time). In some embodiments, the computing device may determine an operational parameter for an energy storage unit as a length of the period of time (e.g., 1 day, 2 days, 5 days, 10 days, 20 days, 50 days, 100 days, 200 days, 300 days, etc.). The determined length of the period of time may be represented in any desired manner (e.g., in seconds, in minutes, in hours, in days, in months, in years, etc.).

In some embodiments, the computing device may determine an operational parameter for an energy storage unit as a capacity of the energy storage unit at a beginning of the period of time. The capacity of the energy storage unit at the beginning of the period of time may include, for example, a capacity of the energy storage unit measured at the beginning of the period of time. For example, at the beginning of the period of time, the energy storage unit may be fully charged (e.g., to 100% of the capacity) and then fully discharged (e.g., to 0% of the capacity), and the amount of energy output by the energy storage unit during this discharging may correspond to the measured capacity of the energy storage unit at the beginning of the period of time. The capacity of the energy storage unit at the beginning of the period of time may be measured in any other desired method. In some examples, the capacity of the energy storage unit at the beginning of the period of time may include a predicted capacity of the energy storage unit at the beginning of the period of time (e.g., a predicted capacity determined using any desired method, such as using the processes as described herein). For example, the predicted capacity of the energy storage unit at the beginning of the period of time may be determined using historical data prior to the period of time. With reference to FIG. 4, in step 416, the computing device may determine one or more operational parameters of the energy storage unit for the period of time.

Disclosed embodiments include providing, to a machine learning model, the one or more operational parameters and one or more load collectives of the plurality of load collectives. For example, the computing device may provide, to a machine learning model, the one or more operational parameters and one or more load collectives of the plurality of load collectives. In some examples, the computing device may provide, to a machine learning model, a subset of the one or more operational parameters as desired, and one or more load collectives of the plurality of load collectives. For example, the computing device may make data of operational parameters and load collectives available to the machine learning model, and/or may allow the machine learning model to access the data. In some embodiments, the machine learning model includes a support vector machine (SVM), a relevance vector machine (RVM), or a model based on extreme gradient boosting (XGBoost). In some examples, the machine learning model may include a support vector machine with a gaussian kernel. In some examples, the machine learning model may include a linear relevance vector machine (e.g., with a gaussian kernel) or a non-linear relevance vector machine (e.g., with a gaussian kernel). Additionally or alternatively, the machine learning model may include any type of suitable model for generating a prediction associated with the energy storage unit based on input data.

The one or more load collectives provided to the machine learning model for processing may include a portion or entirety of the plurality of generated load collectives. In some embodiments, the one or more load collectives include a subset of the plurality of load collectives. For example, a portion of the plurality of load collectives may be provided to and/or processed by the machine learning model, and a remaining portion of the plurality of load collectives may not be provided to and/or processed by the machine learning model. Disclosed embodiments include determining, based on a feature reduction technique, the one or more load collectives of the plurality of load collectives. For example, the computing device may determine, based on a feature reduction technique, the one or more load collectives of the plurality of load collectives. A feature reduction technique may refer to, for example, any methods or processes that may allow for a reduction of data items (e.g., features) as inputs to a machine learning model. The machine learning model may receive data associated with load collectives as inputs to the machine learning model (e.g., the quantities of cycles as indicated in load collectives may be input to the machine learning model and may be used to set the values of input nodes of the machine learning model). The feature reduction technique may enable the determination of a reduced quantity of load collectives, from the plurality of load collectives, to be used or processed by the machine learning model. Using the feature reduction technique, the one or more load collectives to be provided to the machine learning model may be determined to be a reduced set (e.g., a subset) of load collectives from the plurality of load collectives. The feature reduction technique may enable the machine learning model to have a smaller number of input variables, and may provide the benefit of reducing computational complexity associated with the machine learning model.

The feature reduction technique may include, for example, one or more of various types of suitable processes. As one example, a load collective may not be included in the reduced set of load collectives if the load collective is deemed insignificant in terms of the magnitude of its indicated quantity of cycles. For example, if the value of the quantity (e.g., the number of cycles) indicated in the load collective (e.g., as repeatedly determined for each of various periods of time, or for each of various energy storage units) does not satisfy (e.g., meet or exceed) a threshold (e.g., 2, 3, 5, 10, 20, or any other desired number), the load collective may not be included in the reduced set of load collectives.

In some examples, different types of feature reduction techniques may be used for different types of machine learning models. For example, the least absolute shrinkage and selection operator (LASSO) may be used as a regression analysis method. A penalty to linear regression models (e.g., based on L1 regularization) may be introduced, which may force weak features to have a coefficient of zero (0). Additionally or alternatively, for tree-based methods, when training a random forest or gradient boost model, the amount by which each feature may reduce the weighted impurity (e.g., corresponding to variance in the case of regression) of each tree may be calculated. The impurity reduction by each feature may be then averaged across all trees. This average may be considered as a feature importance and may be used to rank features. The computing device may be configured to set a threshold (e.g., an average feature importance score) and remove any features below the threshold. This may be applicable to various types of models, such as random forest or extreme gradient boosting (XGBoost) models. Additionally or alternatively, for recursive techniques, recursive feature eliminations may remove features by testing out linear models with a smaller and smaller quantity of features. It may start with the full dataset, may train the linear model, may calculate the coefficients, and may remove the least important features (e.g., associated with lowest coefficients). The procedure may be repeated recursively until the desired number of features to be selected is reached. In some examples, support vector machines with a linear kernel may be used as the machine learning model.

The reduced set of load collectives may be determined based on using one or more of the feature reduction techniques (e.g., as discussed above). In some examples, the reduced set of load collectives may be determined based on using one feature reduction technique. In some examples, the reduced set of load collectives may be determined based on applying multiple passes of feature reduction techniques. In some examples, the reduced set of load collectives may be determined based on selecting load collectives that may be selected by two or more applied feature reduction techniques.

In some examples, categorical variables may be created of the location (e.g., the site) of the energy storage unit, and may be used as input to the machine learning model. A categorical variable may indicate, for example, the location of the energy storage unit. In some examples, one location may be mapped to a categorical variable. In some examples, multiple locations (e.g., associated with different energy storage units) may be mapped to a categorical variable. In some examples, one location may be mapped to multiple categorical variables (e.g., based on multiple characteristics with which the location may be associated, such as latitude, longitude, climate classification, weather statistics, energy storage types or configurations, etc.). The machine learning model may receive categorical variable(s) as input.

With reference to FIG. 4, in step 418, the computing device may provide, to a machine learning model, the one or more operational parameters and one or more load collectives of the plurality of load collectives.

Disclosed embodiments include generating, based on the machine learning model, a predicted capacity of the energy storage unit at an end of the period of time. For example, the computing device may generate, based on the machine learning model, a predicted capacity of the energy storage unit at an end of the period of time. The predicted capacity may be generated based on the machine learning model processing received data (e.g., the data provided to the machine learning model, such as operational parameters, load collectives, categorical variables, etc.). For example, the machine learning model may include a number of input nodes, one or more intermediate nodes, and an output node (the relationships or interconnectivities among the nodes may be configured during the training of the machine learning model). Each of the input nodes may correspond to a particular item in the received data. For input nodes corresponding to load collectives (e.g., the reduced set of load collectives), the value of each input node may be set to the value of the quantity of cycles indicated in the corresponding load collective. Input nodes for other types of data items (e.g., operational parameters or categorical variables) may be set to the values associated with the corresponding data items. Based on the relationships or interconnectivities among the nodes of the machine learning model, the input values to the input nodes may trigger other nodes of the machine learning model, and may cause the output node to generate a value corresponding to the predicted capacity of the energy storage unit at the end of the period of time. A capacity of the energy storage unit may refer to, for example, a maximum amount of energy that the energy storage unit may store at a particular time (e.g., the capacity may be represented in any desired manner, such as using megawatt hour (MWh)). With reference to FIG. 4, in step 420, the computing device may generate, based on the machine learning model, a predicted capacity of the energy storage unit at an end of the period of time.

Disclosed embodiments include configuring, based on the predicted capacity, the one or more energy storage units. For example, the computing device may configure, based on the predicted capacity, the one or more energy storage units. The configuring of the one or more energy storage units based on the predicted capacity may include any desired processes or actions directed towards the one or more energy storage units. Disclosed embodiments include configuring, based on the predicted capacity, the one or more energy storage units by one or more of: adjusting a pattern for the one or more energy storage units to dispatch electricity, or augmenting a capacity of the one or more energy storage units. For example, the computing device may configure, based on the predicted capacity, the one or more energy storage units by one or more of: adjusting a pattern for the one or more energy storage units to dispatch electricity, or augmenting a capacity of the one or more energy storage units. In some embodiments, the pattern includes a plurality of time intervals during which the one or more energy storage units are configured to charge or discharge at a particular rate. Additionally or alternatively, the pattern may indicate the manner in which the one or more energy storage units may be configured to input or output electricity. For example, if the predicted capacity indicates a reduction from a previous capacity of the energy storage unit and the reduction satisfies (e.g., meets or exceeds) a threshold of a capacity reduction rate, the computing device may determine that the energy storage unit may be overused, and/or may adjust the pattern for dispatching (e.g., inputting and/or outputting) electricity to reduce the usage of the energy storage unit and/or to reduce the rate in which the capacity of the energy storage unit may reduce. In some examples, the computing device may cause augmenting of a capacity of the one or more energy storage units, based on the predicted capacity of the energy storage unit. For example, based on determining that the predicted capacity is below a threshold capacity, the computing device may determine that the one or more energy storage units may be augmented in terms of the capacity. In some examples, the computing device may send a notification (e.g., to an operator of the energy storage unit) regarding augmenting the capacity, and/or trigger a purchase or obtaining of additional energy storage (e.g., energy storage unit(s)) to be added to the group of the one or more energy storage units so that the capacity may be augmented. With reference to FIG. 4, in step 422, the computing device may configure, based on the predicted capacity, the one or more energy storage units.

Disclosed embodiments include training the machine learning model using historical data including one or more of: load collectives of the energy storage unit for a prior period of time before the period of time; operational parameters of the energy storage unit for the prior period of time; or a measured capacity of the energy storage unit at an end of the prior period of time. For example, the computing device may train the machine learning model using historical data. The training of the machine learning model may use any suitable training algorithm. A data set for training the machine learning model may be based on, for example, historical data associated with operation of the energy storage unit for prior time periods (which may be used to calculate, e.g., load collectives, operational parameters, etc.) and the measured capacity of the energy storage unit at the end of each of the prior time periods. Inputs to the machine learning model may include operational parameters, load collectives, and/or categorical variables associated with the energy storage unit, and the machine learning model may output a predicted capacity of the energy storage unit at the end of the period of time. The training of the machine learning model may include, for example, supervised learning. The training of the machine learning model may include, for example, modifying parameters of the machine learning model, so that the machine learning model may produce, based on a particular set of input data, an output (e.g., a predicted capacity at the end of a time period) that may approach the capacity of the energy storage unit at the end of the time period as indicated in the historical data (e.g., an output that may approach a measured capacity of the energy storage unit at the end of the time period). Additionally or alternatively, validation and testing of the trained machine learning model may be performed, for example, using a validation data set or a testing data set. The validation data set or testing data set may be established in a similar manner as the data set for training (e.g., using historical data associated with the energy storage unit).

In some examples, multiple machine learning models (e.g., of the same type or different types) may be trained, and one or more machine learning models may be selected for use from the trained multiple machine learning models based on their respective performance scores (e.g., selecting the one or more machine learning models with highest performance score(s)). A performance score may include any suitable metric for evaluating the performance of a machine learning model (e.g., the mean absolute percentage error (MAPE), the coefficient of determination (e.g., the metric of R squared), etc.). In some examples, the hyperparameters of a machine learning model (e.g., which may specify an aspect of the structure of the machine learning model, such as the number, configuration, and/or structure of nodes, layers, trees, and/or other elements that the machine learning model may include, or an aspect of the learning process for the machine learning model, such as a learning rate that may indicate the step size at each iteration while moving towards a minimum of a loss function) may be adjusted to improve the performance score of the machine learning model. In some examples, a machine learning model (e.g., as trained) may be tested, and its performance (e.g., a performance score) may be evaluated, based on comparing the machine learning model's predictions with predicted results generated using other suitable model(s) (e.g., an autoregressive integrated moving average (ARIMA) model, for example, which may use a time series of historical data of the capacity of an energy storage unit to predict a future capacity of the energy storage unit).

Disclosed embodiments include calculating a degree of influence of each input item of a plurality of input items to the machine learning model on an output of the machine learning model. For example, the computing device may calculate a degree of influence of each input item of a plurality of input items to the machine learning model on an output of the machine learning model. An input item to the machine learning model may include, for example, data corresponding to an input node of the machine learning model. An output of the machine learning model may include, for example, data corresponding to an output node of the machine learning model. The degree of influence may refer to, for example, a degree of any type of effect, impact, control, guidance, or direction that an input item to the machine learning model may have on the output of the machine learning model. In some examples, a change may be applied to each of multiple input items to the machine learning model, and an output change of the machine learning model corresponding to the change to each input item may be determined. The output change corresponding to the change to each input item may indicate a degree of influence of the input item on the output of the machine learning model (e.g., relative to other input items of the multiple input items). In some examples, a Shapley value may be calculated for each input item to the machine learning model to determine the input item's degree of influence on the output of the machine learning model. Other suitable methods for determining the degree of influence may be used.

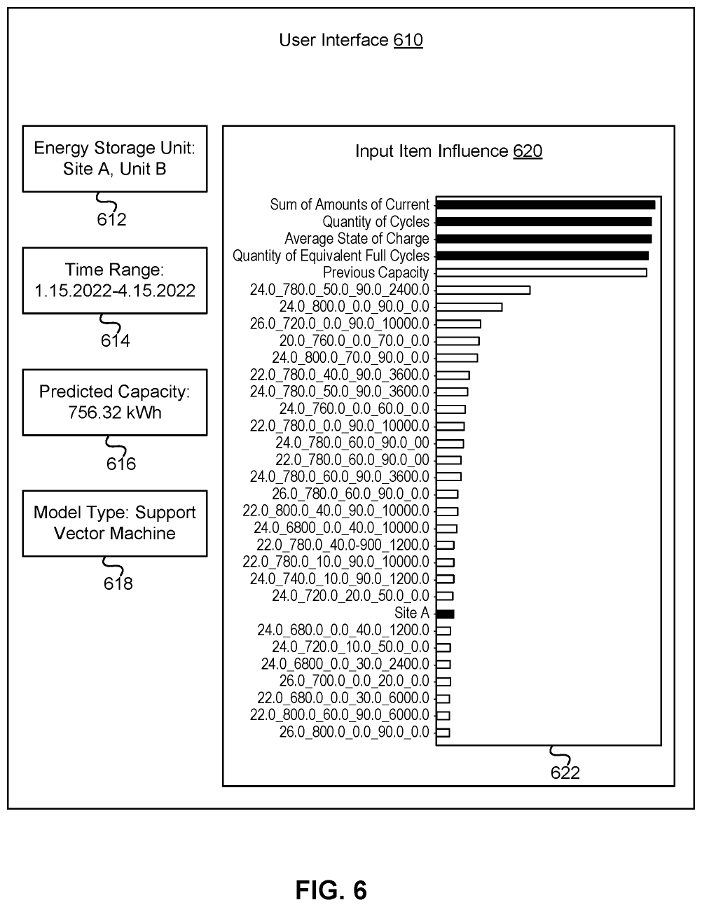

FIG. 6 shows an example user interface 610 associated with using load collectives in energy storage systems, consistent with some embodiments of the present disclosure. In the user interface 610, an indication 612 may identify an energy storage unit (e.g., an energy storage unit identified as Unit B located at Site A). An indication 614 may indicate a time range (e.g., 1.15.2022-4.15.2022) of the period of time for which a predicted capacity of the energy storage unit may be generated (e.g., a predicted capacity of the energy storage unit at the end of the period of time). An indication 616 may indicate a predicted capacity (e.g., 756.32 kWh (kilowatt-hour)) of the energy storage unit at the end of the period of time. An indication 618 may indicate a model type (e.g., a support vector machine) of the machine learning model that may be used to generate the predicted capacity.

An indication 620 may indicate the degree of influence of each input item to the machine learning model on the output of the machine learning model (e.g., the predicted capacity). As an example, the indication 620 may show the degree of influence (e.g., the Shapley value) for each of the input items to the machine learning model, such as operational parameters, load collectives, or categorical variables. The operational parameters may include, for example, “sum of amounts of current” (e.g., a sum of amounts of current of the energy storage unit during the period of time), “quantity of cycles” (e.g., a quantity of cycles, of charging and discharging of the energy storage unit during the period of time, determined using a rain-flow counting algorithm), “average state of charge” (e.g., an average state of charge of the energy storage unit during the period of time), “quantity of equivalent full cycles” (e.g., a quantity of equivalent full cycles of charging and discharging of the energy storage unit during the period of time), “previous capacity” (e.g., a capacity of the energy storage unit at a beginning of the period of time). The load collectives may include, for example, “24.0_780.0_50.0_90.0_2400.0”, “24.0_800.0_0.0_90.0_0.0”, “26.0_720.0_0.0_90.0_10000.0”, or other labels shown in a similar manner. Each label may successively indicate the value of the lower bound of the range of each criterion of the load collective (e.g., the lower bound of a range of a temperature of the energy storage unit, the lower bound of a range of a voltage level of the energy storage unit, the lower bound of a range of a minimum state of charge of the energy storage unit, the lower bound of a range of a maximum state of charge of the energy storage unit, and the lower bound of a range of a sum of amounts of current (e.g., the absolute values of the current) of the energy storage unit). The categorical variables may include, for example, “Site A” (e.g., indicating a location of the energy storage unit).

An indication 622 may indicate the magnitude of the degree of influence (e.g., the Shapley value) for or corresponding to each of the input items to the machine learning model. In some examples, an influence of an input item (e.g., that may positively contribute to the output of the machine learning model) may be, for example, shown using one type of indication (e.g., solid bars), and/or another influence of an input item (e.g., that may negatively contribute to the output of the machine learning model) may be, for example, shown using another type of indication (e.g., empty bars). Any other desired way of showing an influence of an input item may be used. User interface 610 is a unique interface that may bring together a variety of items in a single display, allowing a user to have a comprehensive view. In some examples, user interface 610 may be dynamic and/or may automatically update when the content of any of the indications 612, 614, 616, 618, 620, 622 is changed. In some examples, user interface 610 may include widgets, buttons, pulldown menus, etc., that may allow the indications 612, 614, 616, 618, 620, 622 to be altered. In some examples, user interface 610 may include widgets, buttons, pulldown menus, etc., that may allow the number of items (e.g., the input items to the machine learning model) shown in the indications 620, 622 to be altered.

Disclosed embodiments include determining a degree of similarity between the energy storage unit and another energy storage unit; and based on determining that the degree of similarity satisfies a threshold, using training data for the machine learning model to train a machine learning model for the other energy storage unit. For example, the computing device may determine a degree of similarity between the energy storage unit and another energy storage unit. The degree of similarity may be determined in various manners (e.g., by analyzing the properties, characteristics, or features associated with the energy storage units, such as an energy storage unit's manufacturer, model type, time of production, location of use, etc.). Additionally or alternatively, the degree of similarity may be determined using available operational data for the energy storage units, data indicating cycles of charging and discharging for the energy storage units, and/or data (e.g., time series data) of the temperature, voltage, state of charge, current, etc., associated with the energy storage units. The degree of similarity may be determined, for example, using a distance between vectors of features of the energy storage units, a cosine distance, a cosine similarity, a mathematical technique, and/or other suitable techniques. The computing device may, based on determining that the degree of similarity satisfies a threshold (e.g., a number of same or similar features between the energy storage units), use training data for the machine learning model (e.g., associated with the energy storage unit) to train a machine learning model for the other energy storage unit. The machine learning model for the other energy storage unit may be used to generate predicted capacities of the other energy storage unit (e.g., in a manner similar to that described above).

Disclosed embodiments include a method for using load collectives in energy storage systems, the method including: receiving, by a computing device, operational data associated with an energy storage unit of the one or more energy storage units for a period of time; determining one or more cycles of charging and discharging of the energy storage unit during the period of time; generating, based on the operational data, a plurality of load collectives; determining one or more operational parameters of the energy storage unit for the period of time; providing, to a machine learning model, the one or more operational parameters and one or more load collectives of the plurality of load collectives; generating, based on the machine learning model, a predicted capacity of the energy storage unit at an end of the period of time; and configuring, based on the predicted capacity, the one or more energy storage units. In some embodiments, each load collective of the plurality of load collectives includes: one or more criteria associated with operation of the energy storage unit; and a quantity of cycles, of the one or more cycles, that satisfy the one or more criteria. In some embodiments, the machine learning model includes a support vector machine, a relevance vector machine, or a model based on extreme gradient boosting. In some embodiments, the method further includes determining, based on a feature reduction technique, the one or more load collectives of the plurality of load collectives.

Disclosed embodiments include a non-transitory computer-readable medium for using load collectives in energy storage systems, the non-transitory computer-readable medium storing instructions that, when executed by at least one processor, cause the at least one processor to: receive operational data associated with an energy storage unit of the one or more energy storage units for a period of time; determine one or more cycles of charging and discharging of the energy storage unit during the period of time; generate, based on the operational data, a plurality of load collectives; determine one or more operational parameters of the energy storage unit for the period of time; provide, to a machine learning model, the one or more operational parameters and one or more load collectives of the plurality of load collectives; generate, based on the machine learning model, a predicted capacity of the energy storage unit at an end of the period of time; and configure, based on the predicted capacity, the one or more energy storage units. In some embodiments, each load collective of the plurality of load collectives includes: one or more criteria associated with operation of the energy storage unit; and a quantity of cycles, of the one or more cycles, that satisfy the one or more criteria. In some embodiments, the machine learning model includes a support vector machine, a relevance vector machine, or a model based on extreme gradient boosting. In some embodiments, the instructions, when executed by the at least one processor, further cause the at least one processor to: determine, based on a feature reduction technique, the one or more load collectives of the plurality of load collectives.

Implementation of the method and system of the present disclosure may involve performing or completing certain selected tasks or steps manually, automatically, or a combination thereof. Moreover, according to actual instrumentation and equipment of preferred embodiments of the method and system of the present disclosure, several selected steps may be implemented by hardware (HW) or by software (SW) on any operating system of any firmware, or by a combination thereof. For example, as hardware, selected steps of the disclosure could be implemented as a chip or a circuit. As software or algorithm, selected steps of the disclosure could be implemented as a plurality of software instructions being executed by a computer using any suitable operating system. In any case, selected steps of the method and system of the disclosure could be described as being performed by a data processor, such as a computing device for executing a plurality of instructions.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The systems and techniques described here can be implemented in a computing system that includes a back end component (e.g., as a data server), or that includes a middleware component (e.g., an application server), or that includes a front end component (e.g., a client computer having a graphical user interface or a Web browser through which a user can interact with an implementation of the systems and techniques described here), or any combination of such back end, middleware, or front end components. The components of the system can be interconnected by any form or medium of digital data communication (e.g., a communication network). Examples of communication networks include a local area network (“LAN”), a wide area network (“WAN”), and the Internet. The computing system can include clients and servers. A client and server are generally remote from each other and typically interact through a communication network. The relationship of client and server arises by virtue of computer programs running on the respective computers and having a client-server relationship to each other.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

The foregoing description has been presented for purposes of illustration. It is not exhaustive and is not limited to the precise forms or embodiments disclosed. Modifications and adaptations of the embodiments will be apparent from consideration of the specification and practice of the disclosed embodiments. For example, the described implementations include hardware and software, but systems and methods consistent with the present disclosure may be implemented as hardware alone.

It is appreciated that the above-described embodiments can be implemented by hardware, or software (program codes), or a combination of hardware and software. If implemented by software, it can be stored in the above-described computer-readable media. The software, when executed by the processor can perform the disclosed methods. The computing units and other functional units described in the present disclosure can be implemented by hardware, or software, or a combination of hardware and software. One of ordinary skill in the art will also understand that multiple ones of the above-described modules/units can be combined as one module or unit, and each of the above-described modules/units can be further divided into a plurality of sub-modules or sub-units.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as example only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

It will be appreciated that the embodiments of the present disclosure are not limited to the exact construction that has been described above and illustrated in the accompanying drawings, and that various modifications and changes may be made without departing from the scope thereof. And other embodiments will be apparent to those skilled in the art from consideration of the specification and practice of the disclosed embodiments disclosed herein. It is intended that the specification and examples be considered as exemplary only, with a true scope and spirit of the disclosed embodiments being indicated by the following claims.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application. These examples are to be construed as non-exclusive. Further, the steps of the disclosed methods can be modified in any manner, including by reordering steps or inserting or deleting steps. It is intended, therefore, that the specification and examples be considered as exemplary only, with a true scope and spirit being indicated by the following claims and their full scope of equivalents.

1. A system comprising:
one or more energy storage units; and
a computing device comprising at least one processor and at least one memory storing instructions that, when executed by the at least one processor, cause the computing device to:
receive operational data associated with an energy storage unit of the one or more energy storage units for a period of time;
determine one or more cycles of charging and discharging of the energy storage unit during the period of time;
generate, based on the operational data, a plurality of load collectives, wherein each load collective of the plurality of load collectives includes:
one or more criteria associated with operation of the energy storage unit; and
a quantity of cycles, of the one or more cycles, that satisfy the one or more criteria;
determine one or more operational parameters of the energy storage unit for the period of time;
provide, to a machine learning model, the one or more operational parameters and one or more load collectives of the plurality of load collectives;
generate, based on the machine learning model, a predicted capacity of the energy storage unit at an end of the period of time; and
configure, based on the predicted capacity, the one or more energy storage units.

2. The system of claim 1, wherein the operational data includes one or more of:
a temperature of the energy storage unit during each of a plurality of intervals of the period of time;
a voltage level of the energy storage unit during each of the plurality of intervals of the period of time;
a state of charge of the energy storage unit during each of the plurality of intervals of the period of time; or
an amount of current of the energy storage unit during each of the plurality of intervals of the period of time.

3. The system of claim 1, wherein the instructions, when executed by the at least one processor, further cause the computing device to:
determine the one or more cycles of charging and discharging of the energy storage unit during the period of time using a rain-flow counting algorithm.

4. The system of claim 1, wherein the one or more criteria associated with operation of the energy storage unit comprise one or more of:
a range of a temperature of the energy storage unit;
a range of a voltage level of the energy storage unit;
a range of a minimum state of charge of the energy storage unit;
a range of a maximum state of charge of the energy storage unit;
a range of a sum of amounts of current of the energy storage unit;
a range of a sum of current squared of the energy storage unit during a time segment;
a range of an amount of current of the energy storage unit; or
a range of a depth of charge of the energy storage unit.

5. The system of claim 1, wherein one or more criteria associated with operation of the energy storage unit for a first load collective of the plurality of load collectives are different from one or more criteria associated with operation of the energy storage unit for a second load collective of the plurality of load collectives.

6. The system of claim 1, wherein the one or more operational parameters of the energy storage unit comprise one or more of:
a quantity of cycles, of charging and discharging of the energy storage unit during the period of time, determined using a rain-flow counting algorithm;
a quantity of equivalent full cycles of charging and discharging of the energy storage unit during the period of time;
a sum of amounts of current of the energy storage unit during the period of time;
an average state of charge of the energy storage unit during the period of time;
a length of the period of time; or
a capacity of the energy storage unit at a beginning of the period of time.

7. The system of claim 1, wherein the machine learning model comprises a support vector machine, a relevance vector machine, or a model based on extreme gradient boosting.

8. The system of claim 1, wherein the one or more load collectives comprise a subset of the plurality of load collectives.

9. The system of claim 1, wherein the instructions, when executed by the at least one processor, further cause the computing device to:
determine, based on a feature reduction technique, the one or more load collectives of the plurality of load collectives.

10. The system of claim 1, wherein the instructions, when executed by the at least one processor, further cause the computing device to:
train the machine learning model using historical data including one or more of:
load collectives of the energy storage unit for a prior period of time before the period of time;
operational parameters of the energy storage unit for the prior period of time; or
a measured capacity of the energy storage unit at an end of the prior period of time.

11. The system of claim 1, wherein the instructions, when executed by the at least one processor, further cause the computing device to:
configure, based on the predicted capacity, the one or more energy storage units by one or more of: adjusting a pattern for the one or more energy storage units to dispatch electricity, or augmenting a capacity of the one or more energy storage units.

12. The system of claim 11, wherein the pattern includes a plurality of time intervals during which the one or more energy storage units are configured to charge or discharge at a particular rate.

13. The system of claim 1, wherein the instructions, when executed by the at least one processor, further cause the computing device to:
calculate a degree of influence of each input item of a plurality of input items to the machine learning model on an output of the machine learning model.

14. The system of claim 1, wherein the instructions, when executed by the at least one processor, further cause the computing device to:
determine a degree of similarity between the energy storage unit and another energy storage unit; and
based on determining that the degree of similarity satisfies a threshold, use training data for the machine learning model to train a machine learning model for the other energy storage unit.

15. A method comprising:
receiving, by a computing device, operational data associated with an energy storage unit of the one or more energy storage units for a period of time;
determining one or more cycles of charging and discharging of the energy storage unit during the period of time;
generating, based on the operational data, a plurality of load collectives, wherein each load collective of the plurality of load collectives includes:
one or more criteria associated with operation of the energy storage unit; and
a quantity of cycles, of the one or more cycles, that satisfy the one or more criteria;
determining one or more operational parameters of the energy storage unit for the period of time;
providing, to a machine learning model, the one or more operational parameters and one or more load collectives of the plurality of load collectives;
generating, based on the machine learning model, a predicted capacity of the energy storage unit at an end of the period of time; and
configuring, based on the predicted capacity, the one or more energy storage units.

16. The method of claim 15, wherein the machine learning model comprises a support vector machine, a relevance vector machine, or a model based on extreme gradient boosting.

17. The method of claim 15, further comprising:
determining, based on a feature reduction technique, the one or more load collectives of the plurality of load collectives.

18. A non-transitory computer-readable medium storing instructions that, when executed by at least one processor, cause the at least one processor to:
receive operational data associated with an energy storage unit of the one or more energy storage units for a period of time;
determine one or more cycles of charging and discharging of the energy storage unit during the period of time;
generate, based on the operational data, a plurality of load collectives, wherein each load collective of the plurality of load collectives includes:
one or more criteria associated with operation of the energy storage unit; and
a quantity of cycles, of the one or more cycles, that satisfy the one or more criteria;
determine one or more operational parameters of the energy storage unit for the period of time;
provide, to a machine learning model, the one or more operational parameters and one or more load collectives of the plurality of load collectives;
generate, based on the machine learning model, a predicted capacity of the energy storage unit at an end of the period of time; and
configure, based on the predicted capacity, the one or more energy storage units.

19. The non-transitory computer-readable medium of claim 18, wherein the machine learning model comprises a support vector machine, a relevance vector machine, or a model based on extreme gradient boosting.

20. The non-transitory computer-readable medium of claim 18, wherein the instructions, when executed by the at least one processor, further cause the at least one processor to:
determine, based on a feature reduction technique, the one or more load collectives of the plurality of load collectives.
